(19) United States
(12) Patent Application Publication
(10) Pub. No.: US 2003/0166316 A1
(43) Pub. Date: Sep. 4, 2003

(54) Method of manufacturing field effect transistors

(76) Inventor: Takashi Nakamura, Otsu-shi (JP)

Correspondence Address: JAMES J. CIOFFI, 2070 ROUTE 52, HOPEWELL JUNCTION, NY, 12533, US

(21) Appl. No.: 10/378,576

(22) Filed: Feb. 28, 2003

(30) Foreign Application Priority Data
Mar. 1, 2002 (JP) 2002-055931

(51) Int. Cl. H01L 21/336; H01L 21/8234; H01L 21/425

(52) U.S. Cl. 438/197; 438/528

(57) ABSTRACT

A method of supplying deuterium to MOSFET at low cost and supplying deuterium precisely to a determined depth, in a process of supplying deuterium to MOSFET. The method comprises the steps of: forming an oxide film on a silicon substrate, forming a polysilicon electrode film on the oxide film, and supplying deuterium ions by an ion implanter on the interface of the oxide film 4 and the silicon substrate via the polysilicon electrode film.

### BACKGROUND OF THE INVENTION

1. Field of the Invention

The present invention is related to semiconductor processing and, more particularly, is directed to a method of supplying deuterium in the forming step of MOSFET (Metal Oxide Semiconductor Field Effect Transistor) transistors, which is one of the field effect transistors.

2. Description of Related Art

As transistors are becoming increasingly miniaturized, problems caused by hot electrons are becoming more serious. This is because hot electrons result in a gradual lowering of the threshold voltage of the transistor or a lowering of the conductance of the transistor. That is, the hot electrons induce the aged deterioration of transistors.

Referring to FIG. 9 there is shown a sectional view for explaining the action of hot electrons in a conventional n-channel MOSFET. In the n-channel MOSFET, when the transistor size is miniaturized, while the gate voltage is kept constant, the electric field intensity is increased near the drain. Accordingly, electrons flowing in the channel from the source to the drain acquire a high energy from the high electric field near the drain junction, and become hot electrons.

The hot electrons cause collision ionization at the drain end, and generate electrons and positive holes pairs. The majority of electrons flow into the drain, but some hot electrons flow into the oxide film as gate current (see arrow 1 in FIG. 9). As a result, as time passes, the threshold voltage of the n-channel MOSFET increases, or the conductance decreases, thereby deteriorating the transistor characteristics.

In the proximity of the interface of the silicon substrate and oxide film in this n-channel MOSFET, a silicon dangling bond exists. This is because lattice mismatching occurs in the interface of silicon and silicon dioxide forming the oxide film. Due to the existence of the silicon dangling bond, an energy level called the interface level is generated. When the interface level increases, the threshold voltage increases, which causes an effect on the operation of the n-channel MOSFET.

Previous attempts to solve the problem caused by this silicon dangling bond have focused on bonding hydrogen to the silicon dangling bond, and hydrogenating for terminating. However, when a hot electron collided against this silicon and hydrogen bond (hereinafter referred to as Si—H bond), the Si—H bond was cleaved (see arrow 2 in FIG. 9). Consequently, hydrogen was dissociated from the Si—H bond to generate a silicon dangling bond, thereby increasing the interface level. As the interface level increased, the threshold voltage increased, and the characteristics of the n-channel MOSFET were deteriorated.

Recently, it has been proposed by others to bond deuterium, instead of hydrogen, to the silicon dangling bond and terminate, thereby solving the problems caused by hot electrons. Deuterium has double atomic weight as compared with hydrogen. Hence, the Si-D bond having deuterium bonded to the silicon dangling bond is hardly cleaved in the bond with silicon.

Such methods of supplying deuterium to a device is disclosed, for example, in Japanese Patent Publication No. H8-507175, Japanese Laid-open Patent No. H10-303424, Japanese Laid-open Patent No. H11-274489, and Japanese Laid-open Patent No. 2000-208526. In these proposals, an annealing step at the time of metal wiring is executed by gas containing deuterium, and the deuterium is supplied into the device. Further, the deuterium is supplied into the device by a method of using a deuterium compound (for example, ND₃ and SiD₄) in the raw material when forming a silicon nitride barrier layer for covering the transistor.

In this method of performing the annealing step at the time of metal wiring by gas containing deuterium, about 15 liters of deuterium is needed when converted per wafer. That is, the cost is expensive in the process of supplying deuterium ions in one wafer. Additionally, in the method of supplying deuterium compound (for example, ND₃ and SiD₄) in the raw material for forming a silicon nitride barrier layer for covering the transistor, as converted per wafer, it consumes about 30 milliliters of ND₃ and 150 milliliters of SiD₄. Since the unit price of ND₃ and SiD₄ is expensive, the cost is expensive in the process of supplying deuterium ions in one wafer.

Thus, in the method of annealing by using gas containing deuterium at the time of metal wiring, a large volume of expensive deuterium is needed for the number of layers of metal wiring. In the method of using a deuterium compound, the unit price of the deuterium compound used per wafer is very expensive. Therefore a need exists to avoid the high cost per wafer in the conventional methods of supplying deuterium to the device.

### BRIEF SUMMARY OF THE INVENTION

The purposes and advantages of the present invention have been achieved by providing a method a method of manufacturing a field effect transistor comprising the steps of: forming an oxide film on a silicon substrate; forming a polysilicon electrode film on the oxide film; and supplying deuterium ions through the polysilicon electrode film to an interface of the oxide film and the silicon substrate by an ion implanter.

The invention further provides a method of manufacturing a field effect transistor comprising the steps of: forming an oxide film on a silicon substrate; forming a polysilicon electrode film on the oxide film; etching the polysilicon electrode film to form a gate electrode part; and supplying deuterium ions through the gate electrode part to an interface of the oxide film and the silicon substrate by an ion implanter. The method may further comprise the steps of: forming a spacer made of an insulator around the gate electrode part; and supplying impurity ions on the silicon substrate to form a source region and a drain region, thereby forming a transistor, subsequent to said etching step and prior to said step of supplying deuterium ions through the gate electrode part to an interface of the oxide film and the silicon substrate by an ion implanter. The method may further comprise the step of: forming a silicon nitride barrier layer on the top surface of the transistor subsequent to said step of forming a transistor and prior to said step of supplying deuterium ions through the silicon nitride barrier layer to an interface of the oxide film and the silicon substrate by an ion implanter.

### BRIEF DESCRIPTION OF THE DRAWINGS

FIG. 1 is a flowchart for explaining an embodiment of the present invention.

FIG. 2 is a sectional view for explaining a step of forming an oxide film on a p-type silicon substrate in an embodiment of the present invention.

FIG. 3 is a sectional view for explaining a step of forming a layer of gate electrode part by forming a polysilicon electrode film on the oxide film in an embodiment of the present invention.

FIG. 4 is a sectional view for explaining a process of forming a gate electrode part in an embodiment of the present invention.

FIG. 5 is a sectional view for explaining a process of spacer in an embodiment of the present invention.

FIG. 6 is a sectional view for explaining a process of forming a source region and a drain region in an embodiment of the present invention.

FIG. 7 is a sectional view for explaining a process of forming a silicon nitride barrier layer in an embodiment of the present invention.

FIG. 8 is a sectional view for explaining a process of forming electrodes in an embodiment of the present invention.

FIG. 9 is a sectional view for explaining the action of hot electrons in a conventional n-channel MOSFET.

### DETAILED DESCRIPTION OF THE INVENTION

The present invention relates to a method of supplying deuterium to a MOSFET at low cost and supplying deuterium precisely to a determined depth. The present invention comprises the steps of: forming an oxide film on a silicon substrate, forming a polysilicon electrode film on the oxide film, and supplying deuterium ions by an ion implanter on the interface of the oxide film and silicon substrate via the polysilicon electrode film.

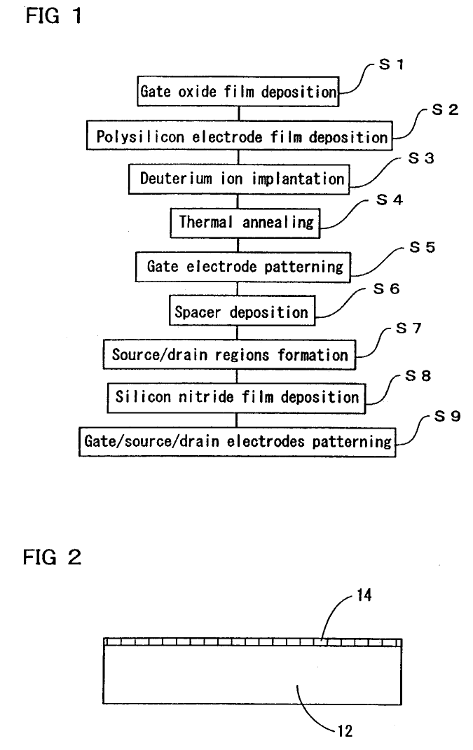

A preferred embodiment of the invention is now described with reference to the accompanying drawings. In the present invention, as shown in FIG. 1, deuterium ions are supplied to a field effect transistor 10 by a step which comprises the sub-steps of: depositing an oxide film 14 on a silicon substrate 12 (S1), depositing a polysilicon electrode film 16 on the oxide film 14 (S2), supplying deuterium ions by an ion implanter on the interface of the oxide film 14 and the silicon substrate 12 via the polysilicon electrode film 16 (S3), heating the deuterium ions so as to be stabilized on a silicon lattice (S4), etching the polysilicon electrode film 16 to pattern a gate electrode part 18 (S5), depositing a spacer 20 made of an insulator around the gate electrode part 18 (S6), supplying impurity ions on the silicon substrate 12 to form a source region 22 and a drain region 24, thereby forming a transistor (S7), depositing a silicon nitride barrier layer 26 on the top surface of the transistor (S8), and forming a contact hole in the silicon nitride barrier layer 26, evaporating aluminum, and patterning an electrode (S9).

In this embodiment, a method of forming n-channel MOSFET is described. In this method of forming n-channel MOSFET, a method of injecting deuterium ions on the interface of the oxide film 14 and silicon substrate 12 is explained. FIG. 2 is a sectional view explaining a step of forming an oxide film 14 on a p-type silicon substrate 12.

As shown in FIG. 2, a silicon substrate 12 which is a p-type silicon wafer is heated in an oxygen atmosphere at a high temperature, and an oxide film 14 is formed. The thickness of the oxide film 14 is deposited to be approximately 100 Å (S1). The thickness of this oxide film 14 is, however, not limited to 100 Å. Depending on the technology to be adopted, the thickness is properly selectable between 10 Å and 200 Å.

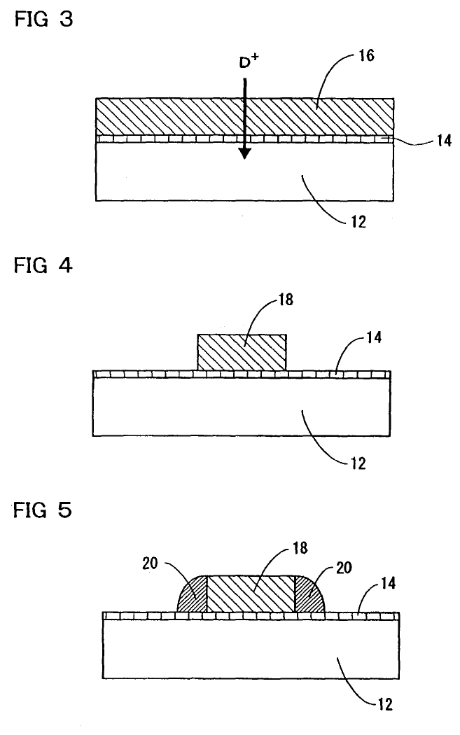

FIG. 3 is a sectional view for explaining a step of forming a layer of gate electrode part 18 by forming a polysilicon electrode film 16 on the oxide film 14. As shown in FIG. 3, the polysilicon electrode film 16 is formed on the top surface of the oxide film 14 by thermal CVD (Chemical Vapor Deposition). The thickness of the polysilicon electrode film 16 is deposited to be approximately 2000 Å (S2). The thickness of this polysilicon oxide film 16 is, however, is not limited to 2000 Å. Depending on the technology to be adopted, the thickness is properly selectable between 1000 Å and 3000 Å.

Next, from above the polysilicon electrode film 16, deuterium ions (D+) are injected by an ion implanter. That is, deuterium ions are injected to the polysilicon electrode film 16 for approximately 10 minutes at a flow rate of approximately 2 milliliters/minute at an electric field acceleration of approximately 10 keV. Thus, deuterium ions are injected near the interface of the oxide film 14 formed beneath the polysilicon electrode film 16 and the silicon substrate 12 (S3). Not limited to the values in this specific example, the flow rate of deuterium ions is properly selectable between 0.5 milliliter/minute and 5 milliliters/minute depending on the technology to be adopted. The duration is selectable between 1 minute and 30 minutes. The energy is selectable between 1 keV and 80 keV.

In this sheet type high speed heat treatment machine the silicon wafer is subsequently heated for approximately 30 minutes at approximately 400 degrees centigrade, and deuterium ions are stabilized on the silicon lattice. As a result, the Si-D bond is formed near the interface of the silicon substrate 12 and oxide film 14 (S4). Not limited to the values in this specific example, the temperature of heat treatment is properly selectable between 400 degrees centigrade and 550 degrees centigrade. The duration is properly selectable between 30 minutes and 60 minutes.

FIG. 4 is a sectional view for explaining a process of forming a gate electrode part 18. As shown in FIG. 4, a gate electrode 18 is patterned on the polysilicon electrode film 16 by anisotropic etching (S5). FIG. 5 is a sectional view for explaining a process of forming a spacer 20 (side wall insulating film). A silicon oxide film is deposited on the entire surface of a wafer, and the film is removed from an unnecessary part by the anisotropic etching. As shown in FIG. 5, a spacer 20 is deposited around the gate electrode part 18 (S6).

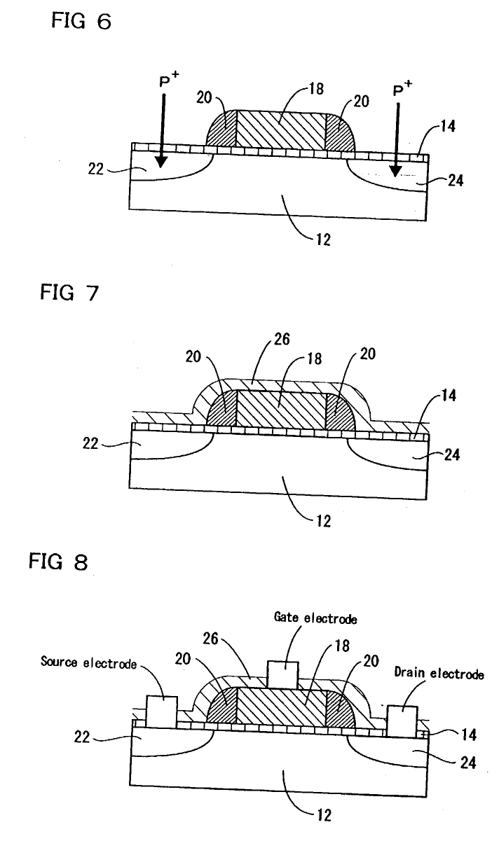

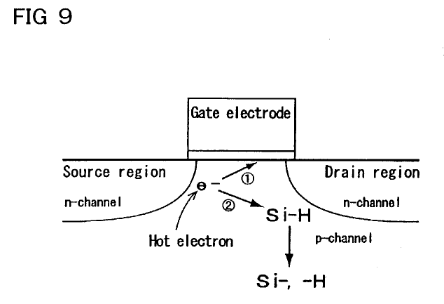

FIG. 6 is a sectional view for explaining a process of forming a source region 22 and a drain region 24. As shown in FIG. 6, phosphorus ions (P+) are injected on the silicon substrate 12 at both sides of the spacer 20 by using an ion implanter. Thus, n-type impurity regions 22, 24 are formed. These are the source regions 22 and drain region 24 of the n-channel MOSFET (S7).

FIG. 7 is a sectional view for explaining a process of forming a silicon nitride barrier layer 26. As shown in FIG. 7, a silicon nitride barrier layer 26 is formed to cover the top surface of the n-channel MOSFET formed on the n-type silicon substrate 12. That is, by depositing a silicon nitride film by thermal CVD, a silicon nitride barrier layer 26 is deposited (S8). This deposition of silicon nitride film is not limited to the thermal CVD process, but may also be formed by plasma CVD.

FIG. 8 is a sectional view for explaining a process of forming electrodes. After forming the silicon nitride barrier layer 26, an oxide film is formed on the silicon nitride barrier layer 26. Consequently, contact holes are formed, corresponding to the gate electrode part 18, source region 22, and drain region 24. The contact holes are filled with tungsten. After evaporating an aluminum film by sputtering, and a patterning process is carried out, and then a gate electrode, a source electrode, and a drain electrode are patterned (S9).

The operation in the embodiment of the present invention is now explained. In this embodiment, after forming the polysilicon electrode film 16, deuterium ions are injected near the interface of the silicon oxide film 14 and polysilicon substrate 12. This is because deuterium ions can be controlled easily by injecting ions to a depth position of approximately total thickness (2100 Å) of the thickness (2000 Å) of the polysilicon electrode film 16 and the thickness (10 Å) of the silicon oxide film 14.

As a result, an Si-D bond exists near the interface of the silicon oxide film 14 and silicon substrate 12, and the interface level by hot electrons is not increased, and hence the threshold voltage of the transistor is not increased. Moreover, since deuterium ions are supplied by an ion implanter, deuterium ions can be supplied in a stable manner at a precisely predetermined depth.

In the method of supplying deuterium ions of the embodiment, deuterium ions are injected by an ion implanter. Therefore, the amount of deuterium is only about 1.5 milliliters for each wafer. In the conventional method of supplying deuterium ions, about 15 liters of deuterium was used. In the embodiment, hence, deuterium can be supplied to the n-channel MOSFET at a notably lower cost.

In the present invention, moreover, deuterium ions may be supplied to the field effect transistor 10 in a step which comprises the sub-steps of: forming an oxide film 14 on a silicon substrate 12, forming a polysilicon electrode film 16 on the oxide film 14, etching the polysilicon electrode film 16 to form a gate electrode part 18, and supplying deuterium ions by an ion implanter on the interface of the oxide film 14 and the silicon substrate 12 via the gate electrode part 18.

Where this method differs from the method of the foregoing embodiment is that deuterium ions are injected after forming the gate electrode part 18 by etching. Other processes are the same as in the method specifically explained in the foregoing embodiment. Thus, by supplying deuterium ions after forming the gate electrode part 18 by etching, deuterium ions can be injected near the interface of the silicon substrate 12 and oxide film 14.

In the present invention, alternatively, deuterium ions may be supplied to the field effect transistor 10 in a step which comprises the sub-steps of forming an oxide film 14 on a silicon substrate 12, forming a polysilicon electrode film 16 on the oxide film 14, etching the polysilicon electrode film 16 to form a gate electrode part 18, supplying impurity ions on the silicon substrate 12 to form a source region 22 and a drain region 24, thereby forming a transistor, and supplying deuterium ions by an ion implanter on the interface of the oxide film 14 and the silicon substrate 12 via the gate electrode part 18.

Where this method differs from the method of the foregoing embodiments is that deuterium ions are injected after forming the source region 22 and the drain region 24. Other processes are the same as in the method specifically explained in the foregoing embodiments. Thus, by supplying deuterium ions after forming the source region 22 and the drain region 24, deuterium ions can be injected near the interface of the silicon substrate 12 and the oxide film 14.

In the present invention, further, deuterium ions may be supplied to the field effect transistor 10 in a step which comprises the sub-steps of: forming an oxide film 14 on a silicon substrate 12, forming a polysilicon electrode film 16 on the oxide film 14, etching the polysilicon electrode film 16 to form a gate electrode part 18, forming a spacer 20 made of an insulator around the gate electrode part 18, supplying impurity ions on the silicon substrate 12 to form a source region 22 and a drain region 24, thereby forming a transistor, forming a silicon nitride barrier layer 26 on the top surface of the transistor, and supplying deuterium ions by an ion implanter on the interface of the oxide film 12 and the silicon substrate 12 via the silicon nitride barrier layer 26.

Where this method differs from the method of the foregoing embodiments is that deuterium ions are injected after forming the silicon nitride barrier layer 26. Other processes are the same as in the method specifically explained in the foregoing embodiments. Thus, by supplying deuterium ions after forming the silicon nitride barrier layer 26, deuterium ions can be injected near the interface of the silicon substrate 12 and oxide film 14.

The process of heat treatment for stabilizing deuterium ions on the silicon lattice is not limited to the process right after supplying of deuterium ions. For example, heat treatment for forming the silicon nitride barrier layer 26 may also be adopted for stabilizing deuterium ions. In the embodiments, the n-channel MOSFET is explained, but this is not limited. The present invention may also be applied in a p-channel MOSFET or a CMOSFET.

In these embodiments, phosphorus is used as an impurity, but the present invention is not limited to these embodiments. Arsenic or antimony may be used in the n-type. Boron or indium may be used in the p-type. In these embodiments, the thickness of the oxide film 14 is 100 Å and the thickness of the polysilicon electrode film 16 is 2000 Å, but the present invention is not limited to these embodiments. For example, a field effect transistor may be formed by further reducing the thickness of the oxide film 14 and polysilicon electrode film 16.

The ion implanter for supplying deuterium ions in the embodiments may be the same as the ion implanter used for forming the source region 22 and drain region 24. The heat treatment machine for stabilizing deuterium ions in the embodiments may be same as the heat treatment machine used for forming the source region 22 and the drain region 24. The method of manufacturing the field effect transistor 10 of the present invention has thus been described by referring to the drawings, but the present invention is not limited to the illustrated embodiments. The invention may be changed, revised or modified in various forms according to the knowledge of those skilled in the art within the scope which do not depart from the spirit of the invention.

According to the present invention, since deuterium ions are supplied in the device by the ion implantation method in the process of supplying deuterium ions to a field effect transistor, consumption of deuterium ions is small, and hence deuterium ions can be supplied to the field effect transistor at low cost. Further, since deuterium ions are supplied to the device by ion implantation method, deuterium ions can be supplied precisely at a predetermined depth.

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

What is claimed is:

1. A method of manufacturing a field effect transistor comprising the steps of:
forming an oxide film on a silicon substrate;
forming a polysilicon electrode film on the oxide film; and
supplying deuterium ions through the polysilicon electrode film to an interface of the oxide film and the silicon substrate by an ion implanter.

2. The method of claim 1, further comprising the step of heating said deuterium ions so as to be stabilized on a silicon lattice.

3. The method of claim 1, wherein said step of forming the oxide film includes a thermal oxidation method.

4. The method of claim 1, wherein said step of forming the polysilicon electrode film includes thermal CVD.

5. A method of manufacturing a field effect transistor comprising the steps of:
forming an oxide film on a silicon substrate;
forming a polysilicon electrode film on the oxide film;
etching the polysilicon electrode film to form a gate electrode part; and
supplying deuterium ions through the gate electrode part to an interface of the oxide film and the silicon substrate by an ion implanter.

6. The method of claim 5, further comprising the steps of:
forming a spacer made of an insulator around the gate electrode part; and
supplying impurity ions on the silicon substrate to form a source region and a drain region, thereby forming a transistor, subsequent to said etching step and prior to said step of supplying deuterium ions through the gate electrode part to an interface of the oxide film and the silicon substrate by an ion implanter.

7. The method of claim 6, further comprising the step of:
forming a silicon nitride barrier layer on the top surface of the transistor subsequent to said step of forming a transistor and prior to said step of supplying deuterium ions through the silicon nitride barrier layer to an interface of the oxide film and the silicon substrate by an ion implanter.

8. The method of claim 5, further comprising the step of heating said deuterium ions so as to be stabilized on a silicon lattice.

9. The method of claim 6, wherein said step of forming the transistor includes a step of injecting ions of phosphorus, arsenic and antimony on the silicon substrate.

10. The method of claim 6, wherein said step of forming the transistor includes a step of injecting ions of boron and indium on said silicon substrate.

11. The method of claim 5, wherein said step of forming the oxide film includes a thermal oxidation method.

12. The method of claim claim 5, wherein said step of forming the polysilicon electrode film includes thermal CVD.

13. The method of claim 5, wherein said step of forming the gate electrode part includes anisotropic etching.

14. The method of claim 6, further comprising the step of heating said deuterium ions so as to be stabilized on a silicon lattice.

15. The method of claim 7, further comprising the step of heating said deuterium ions so as to be stabilized on a silicon lattice.

16. The method of claim 7, wherein said step of forming the transistor includes a step of injecting ions of phosphorus, arsenic and antimony on the silicon substrate.

17. The method of claim 7, wherein said step of forming the transistor includes a step of injecting ions of boron and indium on said silicon substrate.

18. The method of claim 6, wherein said step of forming the oxide film includes a thermal oxidation method.

19. The method of claim 7, wherein said step of forming the oxide film includes a thermal oxidation method.

20. The method of claim 6, wherein said step of forming the polysilicon electrode film includes thermal CVD.
